(19) United States
(12) Patent Application Publication
(10) Pub. No.: US 2009/0236127 A1
(43) Pub. Date: Sep. 24, 2009

(54) ELECTRONIC DEVICE

(75) Inventor: Kenji KOBAE, Kawasaki (JP)

Correspondence Address: Fujitsu Patent Center;C/O CPA Global, P.O. Box 52050, Minneapolis, MN, 55402, US

(73) Assignee: FUJITSU LIMITED, Kawasaki (JP)

(21) Appl. No.: 12/408,749

(22) Filed: Mar. 23, 2009

(30) Foreign Application Priority Data
Mar. 24, 2008 (JP) 2008-076179

(51) Int. Cl. H05K 1/02

(52) U.S. Cl. 174/255

(57) ABSTRACT

An electronic device comprises a substrate; a wiring pattern which is provided on a front surface of the substrate, and which includes a plurality of connection ends; a circuit component which houses a circuit, and which includes bumps, electrically connected to the circuit, that project from a specific surface of the circuit component, and which is disposed with the specific surface facing the front surface of the substrate; conductive members which electrically connect the bumps of the circuit component and the connection ends of the wiring pattern, and which fix the circuit component to the substrate; and guide sections which are provided on the substrate, and to each of which the conductive member forced out of an interval above the corresponding connection end is guided to prevent the conductive member from reaching a connection end other than the corresponding connection end.

### CROSS-REFERENCE TO RELATED APPLICATIONS

This application is based upon and claims the benefit of priority from the prior Japanese Patent Application No. 2008-76179 filed on Mar. 24, 2008, the entire contents of which are incorporated herein by reference.

### FIELD

The present invention relates to an electronic device wherein a circuit component having a built-in circuit is packaged on a wiring substrate.

Heretofore, various RFID (Radio Frequency Identification) tags which exchange information with external equipment such as a reader/writer, in non-contact fashion with electric waves, have been extensively employed. Many of such RFID tags have a structure wherein a circuit component having a built-in circuit for communicating through an antenna pattern with the external equipment as stated above is packaged on a wiring substrate in which the antenna pattern for the electric wave communications is provided on a base made of plastic. Also, the connection between the antenna pattern and the circuit built in the circuit component is performed by the electrical connections between bumps being minute terminals, which are provided in the circuit component and which are electrically joined to the built-in circuit, and the connection ends of the sides of the antenna pattern.

The electrical connections between the bumps and the connection ends have hitherto been performed by a so-called “pressure-welding method” wherein, after the circuit component has been arranged on the wiring substrate so that the bumps may touch the connection ends, this circuit component is pressed against the wiring substrate under a specific pressure (refer to, for example, Patent Document 1 being Japanese Laid-open Patent Publication No. H06-232204). Here, in recent years, the circuit component has been rapidly miniaturized, and the bumps provided in the small-sized circuit component have become very minute. As a result, it has been required in the pressure-welding method to pressure-weld the minute bumps to the connection ends under a very low load. With conventional pressure-welding methods, however, it has been difficult to stabilize the low loads, and the problem of contact malfunctions ascribable to the difficulty often occurs.

Especially in the RFID tag, the antenna pattern is sometimes formed of a pattern of aluminum. With the aluminum pattern, however, an electrical connectivity is liable to degrade due to surface oxidation, and the problem as stated above occurs easily. In the RFID tag, therefore, the pressure-welding method has a narrow margin for the low load for favorably connecting the bumps to the connection ends, and this incurs such a factor for the increase of a cost that a special installation for achieving the favorable connections is necessitated.

Meanwhile, as an example of a technique for connecting two conductors in an electrically favorable state, there has been known a technique wherein the two conductors are bonded to each other with a member of anisotropic conductive resin which, when interposed between the conductors, conducts a current only in a direction coupling the conductors to each other. In accordance with such a technique employing the anisotropic conductive resin member, even when degradation of the electrical connectivity has occurred due to the surface oxidation, the anisotropic conductive resin member can compensate for such degradation. Also, many of the circuit components have a plurality of bumps, and a plurality of connection portions based on the one-to-one electrical connections of the plurality of bumps and the plurality of connection ends are formed by mounting the circuit component on the wiring substrate. On this occasion, short-circuiting needs to be avoided between the plurality of connection portions. Here, a conductivity exists in only the interposition direction in the anisotropic conductive resin member. Therefore, even when, for example, the anisotropic conductive resin members have been roughly bonded so as to encompass the connection portions, the connections of the individual connection portions can be achieved while maintaining the insulation between the connection portions. In this manner, the bonding based on the anisotropic conductive resin members has also the merit that the connections that avoid short-circuiting between the connection portions can be performed with ease.

In the anisotropic conductive resin, the conductivity in the interposition direction is achieved by conductive particles dispersed in the resin. As a result, point connections through the conductive particles become predominant in the connections between the conductors based on such a technique. Therefore, when the bonding which employs the anisotropic conductive resin is applied to the connection in which a contact area is originally small as in the connection between the minute bump and the connection end, a sufficient number of point connections might not be obtained in the small contact area, and it is unreasonable to apply the bonding employing the anisotropic conductive resin, to such a connection of small touch area.

Also, as a technique for enhancing the electrical connectivity between two conductors, there has been known a technique wherein the conductors are bonded by a conductive member which is represented by a conductive adhesive, for example, a solder paste or a silver paste (refer to, for example, Patent Document 2 being Japanese Laid-open Patent Publication No. 10-4122). Also in the conductive member, conductivity is achieved by conductive particles dispersed in a bonding resin. Since, however, these conductive particles are much smaller than the conductive particles in the anisotropic conductive resin, a favorable connectivity can be attained also for the connection of the small contact area as stated before. However, the conductive member does not have the anisotropy of the conductivity as in the anisotropic conductive resin. Therefore, in the case of connecting the plurality of bumps to the conductor pattern as stated before, the bondings can only be performed in individual connection portions in order to avoid short-circuits between the plurality of connection portions. Nevertheless, bondings which avoid the short-circuiting between the connection portions are difficult because, in the miniaturization of the circuit component as stated before, not only are the individual bumps minute, but also the intervals between the bumps are narrow.

In this regard, there has been proposed, for example, a technique wherein grooves or penetrating holes are provided in a wiring substrate, between individual connection ends which are respectively connected with bumps, and conductive members in individual connection portions are separated from each other based on the idea that the conductive members have difficulty entering the grooves or the penetrating holes (refer to, for example, Patent Document 3 being Japanese Laid-open Patent Publication No. 2005-150652).

Also, there has been proposed, for example, a technique wherein, in order to widen the interval between a circuit component and a wiring substrate when the circuit component is mounted on the wiring substrate, the amount the bumps provided in the circuit component protrude from the circuit component is enlarged, thereby to reduce the amount in which conductive members in individual connection portions are peripherally enlarged when pressed by the circuit component, and to avoid the contact between such conductive members (refer to, for example, Patent Document 4 being Japanese Laid-open Patent Publication No. 2001-102715).

### SUMMARY

An electronic device comprises a substrate; a wiring pattern which is provided on a front surface of the substrate, and which includes a plurality of connection ends; a circuit component which houses a circuit, and which includes bumps, electrically connected to the circuit, that project from a specific surface of the circuit component, and which is disposed with the specific surface facing the front surface of the substrate; conductive members which electrically connect the bumps of the circuit component and the connection ends of the wiring pattern, and which fix the circuit component to the substrate; and guide sections which are provided on the substrate, and to each of which the conductive member forced out of an interval above the corresponding connection end is guided to prevent the conductive member from reaching a connection end other than the corresponding connection end.

### BRIEF DESCRIPTION OF THE DRAWINGS

FIGS. 1A and 1B are a schematic top view and a sectional view, respectively, illustrating a first embodiment of an RFID tag for an electronic device;

FIGS. 2A and 2B are a schematic top view and a sectional view, respectively, illustrating a second embodiment of an RFID tag for an electronic device;

FIGS. 3A and 3B are a schematic top view and a sectional view, respectively, illustrating a third embodiment of an RFID tag for an electronic device; and

FIGS. 4A and 4B are a schematic top view and a sectional view, respectively, illustrating a fourth embodiment of an RFID tag for an electronic device.

### DETAILED DESCRIPTION OF THE EMBODIMENTS

Here, regarding the fundamental aspect of the electronic device stated above, the following applied aspects are preferable:

At least one of the guide sections is a substrate portion where a recess into which the conductive member flows is formed in the substrate, and

at least one of the guide sections is a substrate portion where a penetrating hole into which the conductive member flows is formed in the substrate.

According to the preferable applied aspects, the conductive member can be drawn into the recess or the penetrating hole by capillarity, and hence, the conductive member can be effectively guided.

Also, regarding the fundamental aspect of the electronic device, the following applied aspect is preferable:

“At least one of the guide sections is provided in the periphery of the connection end and on a side away from another connection end”.

According to the preferable applied aspect, the conductive members corresponding to the plurality of connection ends may be guided in directions away from each other, and hence, the safer mounting of the circuit component is possible.

First of all the fundamental aspect and a first embodiment which is a practicable embodiment of the electronic device according to the applied aspects will be described.

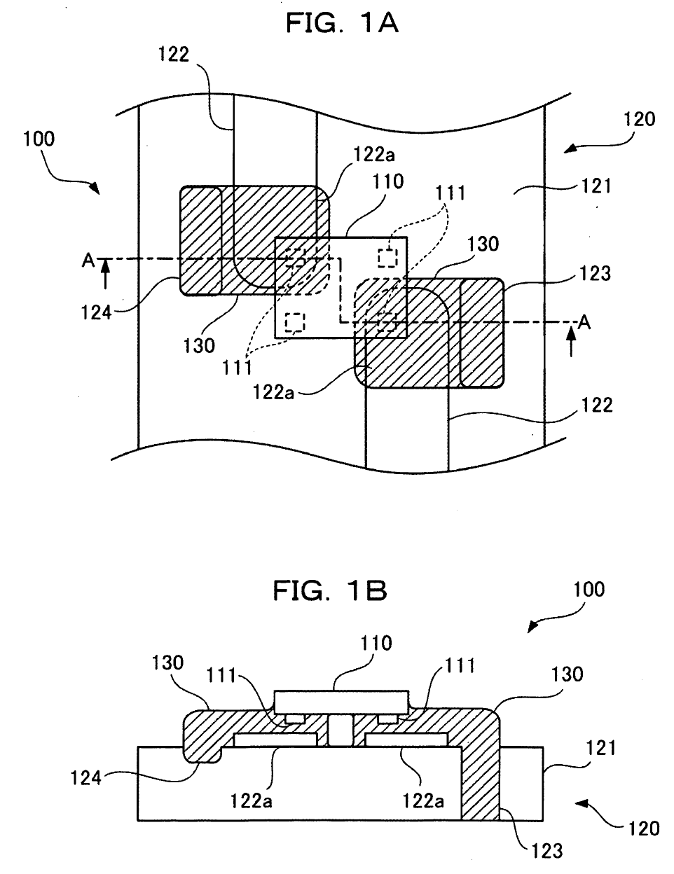

FIGS. 1A and 1B are pattern views illustrating an RFID tag which is a first embodiment of the electronic device.

FIG. 1A is a top view of the peripheral part of a circuit component 110 in the RFID tag 100, while FIG. 1B is a sectional view along line A-A in FIG. 1A, in the RFID tag 100.

The RFID tag 100 illustrated in FIGS. 1A and 1B exchanges information with external equipment, such as a reader/writer, in a non-contact fashion with electric waves. This RFID tag 100 has a structure such that the circuit component 110, in which a circuit for communicating with the aforementioned external equipment through an antenna pattern 122 for electric wave communications is built, is mounted on a wiring substrate 120 in which a base 121 made of a PET film is overlaid with the antenna pattern 122. The base 121, the antenna pattern 122, and the circuit component 110 correspond respectively to examples of a substrate, a wiring pattern, and a circuit component in the fundamental aspect of the electronic device.

The circuit component 110 includes four bumps 111 each of which is electrically joined to the circuit, and the antenna pattern 122 on the wiring substrate 120 has two connection ends 122a each of which is electrically connected with one of the bumps 111. In addition, the electrical connection between the circuit built in the circuit component 110 and the antenna pattern 122 on the wiring substrate 120 is performed by the electrical connections between two diagonally located bumps of the four bumps 111 and the connection ends 122a at positions corresponding to the diagonally located bumps 111, as illustrated in FIG. 1A. The bumps 111 and the connection ends 122a correspond respectively to examples of bumps and connection ends in the fundamental aspect of the electronic device.

Further, in the RFID tag 100, the connections between the bumps 111 and the connection ends 122a are performed by conductive adhesive portions 130 which fix the circuit component 110 onto the surface of the wiring substrate 120, and which electrically connect the two bumps 111 and the two connection ends 122a in one-to-one correspondence to each other. The conductive adhesive portions 130 correspond to an example of conductive members in the fundamental aspect of the electronic device.

In this embodiment, in the base 121, a penetrating hole portion 123 in which a penetrating hole is formed is juxtaposed on the right side of the right connection end 122a as seen in FIG. 1, and at a position spaced away from the connection end 122a. Further, a recess portion 124 in which a recess is formed is juxtaposed on the left side of the left connection end 122a as seen in the figures, and at a position spaced away from the connection end 122a. Here, the penetrating hole portion 123 and the recess portion 124 correspond respectively to examples of guide sections in the fundamental aspect of the electronic device. Also, the penetrating hole portion 123 and the recess portion 124 correspond respectively to examples of the “substrate portion where the penetrating hole is formed in the substrate” and the “substrate portion where the recess is formed in the substrates” in the applied aspect of the electronic device.

The circuit component 110 is mounted on the wiring substrate 120 in such a way that the connection ends 122a of the wiring substrate 120 and/or the bumps 111 of the circuit component 110 are each coated with the conductive adhesive portions 130, that the circuit component 110 is provided on the wiring substrate 120 with the bumps 111 and the connection ends 122a opposed in a one-to-one correspondence, and that the circuit component 110 is pressed onto the wiring substrate 120 under a specific low load. On this occasion, the conductive adhesive portions 130 between the bumps 111 and the connection ends 122a are forced out of the intervals between the connection ends 122a and the bumps 111 and spread to the peripheral parts of these connection ends, by the pressing of the circuit component 110 against the wiring substrate 120. Here in this embodiment, the penetrating hole portion 123 and the recess portion 124 draw the conductive adhesive portions 130 forced out of the intervals between the connection ends 122a and the bumps 111 owing to capillarity. As a result, most of the conductive adhesive portion 130 forced out of the interval between the right connection end 122a and the bump 111 seen in FIG. 1 is guided to the right side of the connection end 122a by the penetrating hole portion 123. On the other hand, most of the conductive adhesive portion 130 forced out of the interval between left connection end 122a and the bump 111 seen in FIG. 1 is guided to the left side of the connection end 122a by the recess portion 124. Thus, the conductive adhesive portions 130 forced out of the intervals between the connection ends 122a and the bumps 111 in the right and left sides (as seen in FIG. 1) are separated from each other, and the contact between both the conductive adhesive portions 130 is avoided. Thus, short-circuiting between the connection portion of the bump 111 and the right connection end 122a and the connection portion of the bump 111 and the left connection end 122a can be reliably avoided.

Here, regarding the fundamental aspect of the electronic device, the following applied aspect is preferable:

At least one of the guide sections is a dummy pattern which is provided on the substrate separately from the connection end and in juxtaposition to the connection end.

In accordance with the preferable applied aspect, a fluid on a substrate that has a pattern can be effectively guided along the conductive member by utilizing the general property that the fluid is liable to flow along the pattern.

Now, the fundamental aspect and a second embodiment which is a practicable embodiment for the electronic device according to the applied aspect will be described.

The second embodiment differs from the first embodiment in how to guide the conductive adhesive portions being examples of the conductive members forced out of the intervals between the connection ends and the bumps. Now, the second embodiment will be described by focusing on the points of difference from the first embodiment.

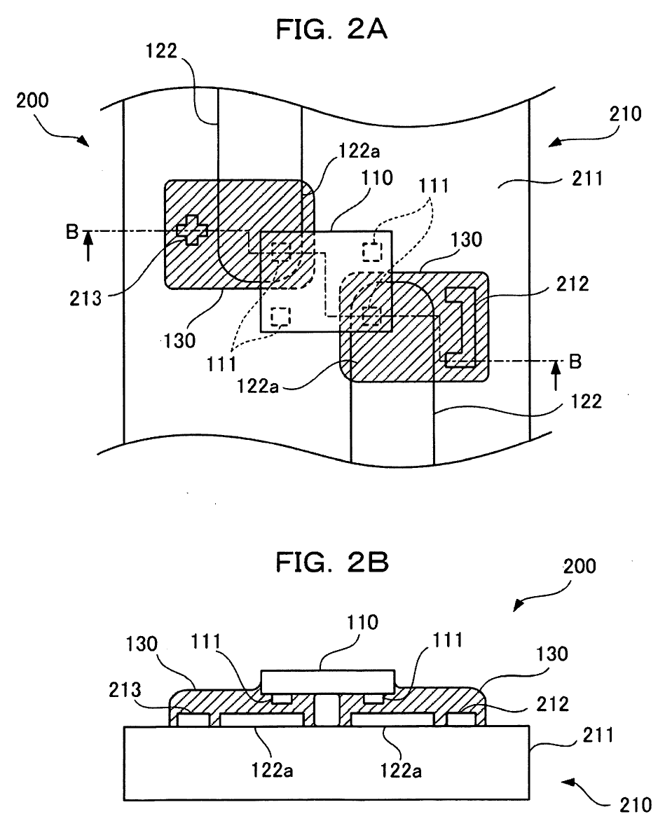

FIGS. 2A and 2B are views of an RFID tag which is a second practicable embodiment for the electronic device. In FIGS. 2A and 2B, elements equivalent to those illustrated in FIGS. 1A and 1B are indicated by affixing the same numerals and signs as in FIGS. 1A and 1B. Thus, the equivalent elements shall be omitted from repeated description.

FIG. 2A is a top view of the peripheral part of a circuit component 110 in the RFID tag 200, while FIG. 2B is a sectional view along line B-B in FIG. 2A, in the RFID tag 200.

In the RFID tag 200 illustrated in FIGS. 2A and 2B, on the base 211 of a wiring substrate 210, a first independent dummy pattern 212 is juxtaposed on the right side of a right connection end 122a as seen in FIG. 2, and at a position spaced away from the connection end 122a. Further, a second independent dummy pattern 213 is juxtaposed on the left side of a left connection end 122a as seen in FIG. 2, and at a position spaced away from this connection end 122a. Here, the first independent dummy pattern 212 and the second independent dummy pattern 213 correspond respectively to examples of guide sections in the fundamental aspect of the electronic device. Also, the first independent dummy pattern 212 and the second independent dummy pattern 213 correspond to examples of dummy patterns in the applied aspect of the electronic device.

The first independent dummy pattern 212 is an isolated pattern which is arranged on the right side of the right connection end 122a as seen in FIG. 2. The shape of the dummy pattern 212 is similar to a right square bracket where the top of the dummy pattern 212 (as seen in FIG. 2A) extends rightwards, bends downwards and extends downwards for a length that is longer than the top portion, and then bends leftwards and extends for a length that approximates the length of the top portion. The second independent dummy pattern 213 is an isolated pattern arranged on the left side of the left connection end 122a as seen FIG. 2, and has a cruciform shape.

In this embodiment, the first independent dummy pattern 212 and the second independent dummy pattern 213 draw conductive adhesive portions 130 forced out of the interval between the connection ends 122a and the bumps 111, by utilizing the general property that the fluid on the substrate having a pattern is liable to flow along the pattern. As a result, most of the conductive adhesive portion 130 forced out of the interval between the right connection end 122a and the bump 111 seen in FIG. 2 is guided to the right side of this connection end 122a by the first independent dummy pattern 212. On the other hand, most of the conductive adhesive portion 130 forced out of the interval between the left connection end 122a and the bump 111 seen in FIG. 2 is guided to the left side of this connection end 122a by the second independent dummy pattern 213. Thus, the conductive adhesive portions 130 forced out of the intervals between the connection ends 122a and the bumps 11 seen in FIG. 2 are separated from each other, and contact between both of the conductive adhesive portions 130 is avoided. Thus, the short-circuiting between the connection portion between the bump 111 and the right connection end 122a and the connection portion between the bump 111 and the left connection end 122a may be reliably avoided.

Here, regarding the fundamental aspect of the electronic device, the following applied aspect is preferable:

At least one of the guide sections is a dummy wiring line which is placed in continuation to a connection end on the substrate.

In accordance with the preferable applied aspect, the conductive member can be guided more effectively by utilizing the general property that a fluid on a substrate having a pattern is liable to flow along the pattern, and by continuing the dummy wiring line for guiding the conductive member to the connection end by the use of such a property.

Now, the fundamental aspect and a third embodiment which is a practicable embodiment for the electronic device according to the applied aspect will be provided.

The third embodiment differs from the foregoing first and second embodiments in how to guide the conductive adhesive portions being examples of the conductive members that have been forced out of the interval between the connection ends and the bumps. Now, the third embodiment will be described by focusing on the points of difference from the first and second embodiments.

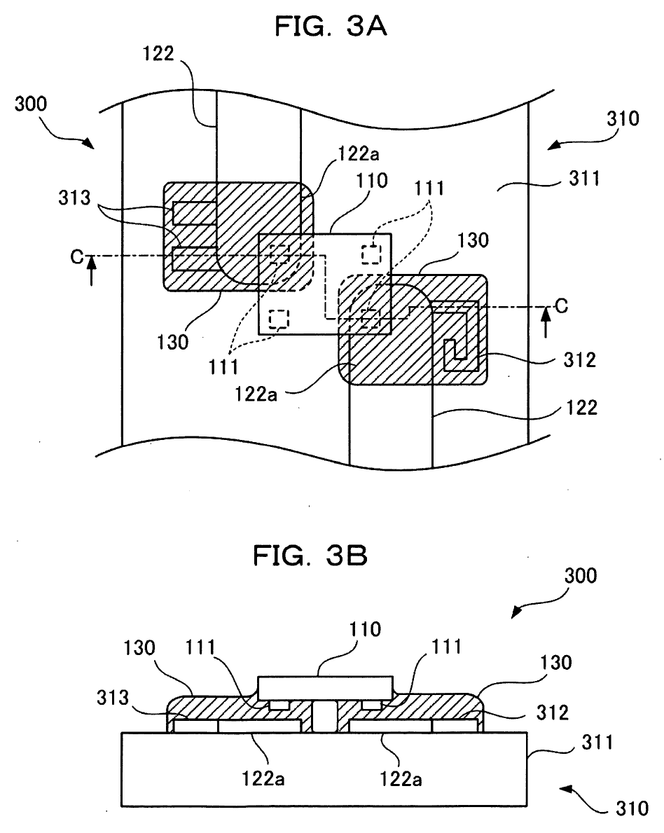

FIGS. 3A and 3B are views of an RFID tag which is a third practicable embodiment for the electronic device. In FIGS. 3A and 3B, elements equivalent to those shown in FIGS. 1A and 1B are indicated by affixing the same numerals and signs as in FIGS. 1A and 1B. Thus, the equivalent elements shall be omitted from repeated description.

FIG. 3A is a top view of the peripheral part of a circuit component 110 in the RFID tag 300, while FIG. 3B is a sectional view along line C-C in FIG. 3A, in the RFID tag 300.

In the RFID tag 300 shown in FIGS. 3A and 3B, on the base 311 of a wiring substrate 310, a first extension dummy pattern 312 which extends rightwards in continuation from a right connection end 122a as seen in FIG. 3 is provided. Further, a second extension dummy pattern 313 which extends leftwards in continuation from a left connection end 122a as seen in FIG. 3 is provided. In this embodiment, the first extension dummy pattern 312 has a pattern shape in which the pattern stretches spirally on the right side of the right connection end 122a as seen in FIG. 3. The second extension dummy pattern 313 is formed of two rectilinear patterns which stretch leftwards from the left connection end 122a as seen in FIG. 3. The first extension dummy pattern 312 and the second extension dummy pattern 313 correspond respectively to examples of guide sections in the fundamental aspect of the electronic device. Also, the first extension dummy pattern 312 and the second extension dummy pattern 313 correspond respectively to examples of dummy wiring lines in the applied aspect of the electronic device.

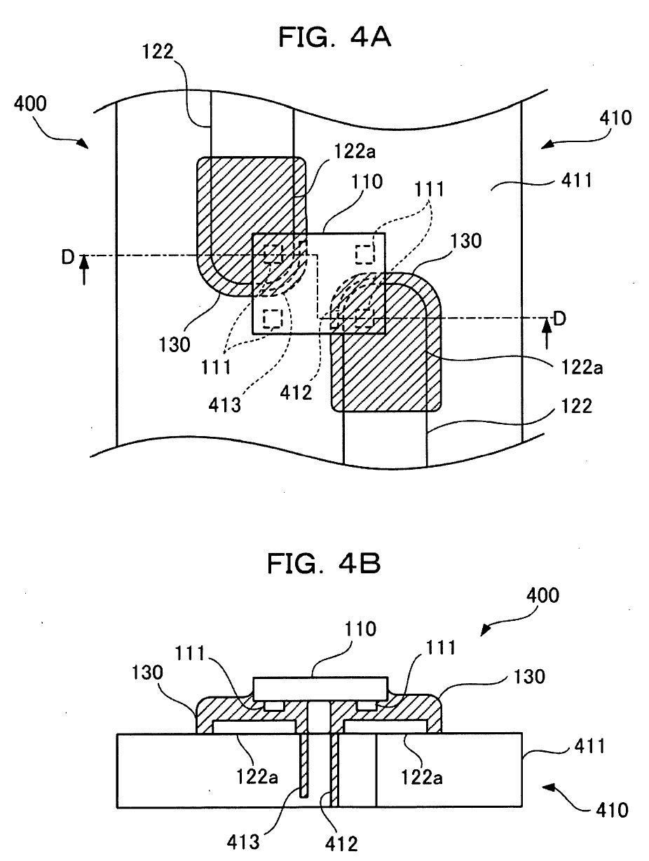

In this embodiment, since the first dummy pattern 312 and the second dummy pattern 313 are provided in continuation to the connections ends 122a, the first dummy pattern 312 and the second dummy pattern 313 forcefully guide the conductive adhesive portion 130 that is forced out of the interval between the connection ends 122a and the bumps 111 by using the general property that fluid is liable to flow along a pattern on a substrate when flowing on a substrate. As a result most of the conductive adhesive portion 130 forced out of the interval between the right connection end 122a and the bump 111 seen in FIG. 3 is guided to the right side of this connection end 122a by the first extension dummy pattern 312. Similarly, most of the conductive adhesive portion 130 forced out of the interval between the left connection end 122a and the bump 111 seen in FIG. 3 is guided to the left side of this connection end 122a by the second extension dummy pattern 313. Thus, the conductive adhesive portions 130 forced out of the intervals between the connection ends 122a and the bumps 111 seen in FIG. 4 are separated from each other, and contact between both the conductive adhesive portions 130 is avoided, so that short-circuiting between the connection portion of a bump 111 and the right connection end 122a and the connection portion of a bump 111 and the left connection end 122a can be reliably avoided.

Here, regarding the fundamental aspect of the electronic device stated above, the following application aspect is preferable:

At least one of the guide sections is provided on the side of the periphery of the connection end which faces the other connection end.

In accordance with the preferable application aspect, conductive members are guided in directions in which they approach each other, while avoiding contact between the conductive members which correspond to the plurality of connection ends, whereby the area of those parts of the substrate which are covered with the conductive members can be suppressed, so that the efficient packaging of the circuit component is permitted.

Now, the fundamental aspect and a fourth embodiment which is a practicable embodiment for the electronic device according to the applied aspect will be described.

The fourth embodiment differs from the foregoing first to third embodiments in how to guide the conductive adhesive portions being examples of the conductive members forced out of the intervals between the connection ends and the bumps. Now, the fourth embodiment will be described by focusing on the points of difference from the first to third embodiments.

FIGS. 4A and 4B are model views showing an RFID tag which is the fourth practicable embodiment for the electronic device. In FIGS. 4A and 4B, elements equivalent to those shown in FIGS. 1A and 1B are indicated by affixing the same numerals and signs as in FIGS. 1A and 1B. Thus, the equivalent elements shall be omitted from repeated description.

FIG. 4A is a top view of the peripheral part of the circuit component 110 in the RFID tag 400, while FIG. 4B is a sectional view along line D-D in FIG. 4A, in the RFID tag 400.

In the RFID tag 400 shown in FIGS. 4A and 4B, on the base 411 of a wiring substrate 410, an arc-shaped penetrating hole portion 412 in which an arc-shaped penetrating hole is provided at a position under the circuit component 110 is juxtaposed on the left side of a right connection end 122a as seen in FIG. 4. Furthermore, an arc-shaped recess portion 413 in which an arc-shaped recess is provided at a position spaced away from a left connection end 122a as seen FIG. 4 is juxtaposed on the right side of the left connection end 122a. In this embodiment, the arc-shaped penetrating hole portion 412 and the arc-shaped recess portion 413 correspond respectively to examples of guide sections in the fundamental aspect of the electronic device.

In this embodiment, the arc-shaped penetrating hole portion 412 and the arc-shaped recess portion 413 draw the conductive adhesive portions 130 forced out of the intervals between the connection ends 122a and the bumps 111. As a result, most of the conductive adhesive portion 130 forced out of the interval between the right connection end 122a and the bump 111 seen in the FIG. 4 is guided to the right side of the connection end 122a by the arc-shaped penetrating hole portion 412. Similarly, most of the conductive adhesive portion 130 forced out of the interval between the left connection end 122a and the bump 111 seen in FIG. 4 is guided to the left side of this connection end 122a by the arc-shaped recess portion 413. Thus, the conductive adhesive portion 130 forced out of the interval between the right connection end 122a and the bump 111 seen in FIG. 4 and the conductive adhesive portion 130 forced out of the interval between the left connection end 122a and the bump 111 seen in FIG. 4 do not contact each other even though they approach each other, so that short-circuiting between the connection portion of a bump 111 and the right connection end 122a and the connection portion of a bump 111 and the left connection end 122a can be reliably avoided. Also, in this embodiment, the conductive adhesive portions 130 forced out of the intervals between the connection ends 122a and the bumps 111 are guided towards each other, so that the area of the parts of the wiring substrate 410 which are covered with the conductive adhesive portions 130 is reduced, and structurally the circuit component 110 may be efficiently mounted on the wiring substrate 410.

RFID tags have been used as examples for the embodiments of the electronic device. However, the electronic device is not restricted as such, and the embodiment may also correspond to a general electronic device in which a circuit component having a built-in circuit is packaged on a wiring substrate, for example, a circuit board that is mounted in a portable telephone or computer or a general domestic electric product.

RFID tags in which the circuit component is exposed when packaged on the wiring substrate have been used as an example in the embodiments of the electronic device. However, the electronic device is not restricted as such, and may be, for example, an electronic device in which the circuit component packaged on the wiring substrate is covered with a specific resin material.

Also, in the above, the RFID tags in each of which an interval exists between the circuit component and the wiring substrate have been used as examples in the embodiments of the electronic device. However, the electronic device is not restricted as such, and may be, for example, an electronic device in which a specific underfill resin is provided between the circuit component and the wiring substrate.

Also, a recess provided in the base of the wiring substrate has been used as an example of a guide section in the fundamental aspect of the electronic device. However, the guide section in the fundamental aspect is not restricted as such, and may be, for example, a recess portion on a wiring pattern in which a recess is provided by etching a recess in a place spaced away from the connection end with the bump or in a place continuous to the connection end, the wiring pattern being thickly formed on the base.

A combination of the recess portion and the penetrating hole portion which are provided in the base of the wiring substrate, a combination of the independent dummy patterns which are formed near the connection ends, and a combination of the extension dummy patterns which are continuous from the connection ends, have been used as examples of the guide sections in the fundamental aspect of the electronic device. However, the guide sections in the fundamental aspect are not restrictive as such, and the guide sections may be, for example, a combination of a recess portion or a penetrating hole portion and the independent dummy pattern, a combination of a recess portion or a penetrating hole portion and the extension dummy pattern, or a combination of the independent dummy pattern and the extension dummy pattern.

As described above, according to the fundamental aspect of the electronic device, a circuit component may be mounted on a wiring substrate in a state where short-circuiting between the electrical connection portions of bumps and connection ends based on conductive members is reliably avoided.

1. An electronic device comprising:
a substrate;
a wiring pattern which is provided on a front surface of said substrate, and which includes a plurality of connection ends;
a circuit component which houses a circuit, which includes bumps projecting from a specific surface and electronically connected to the circuit on the specific surface of said circuit component, and which is disposed with the specific surface facing the front surface of said substrate;
conductive members which electrically connect the bumps of said circuit component and the connection ends of said wiring pattern, and which fix said circuit component to said substrate; and
guide sections which are provided on said substrate, and to each of which the conductive member forced out of the interval above the corresponding connection end is guided to prevent the conductive member from reaching a connection end other than the corresponding connection end.

2. An electronic device as defined in claim 1, wherein at least one of said guide sections is a substrate portion in which a recess for the conductive member to flow thereinto is formed in said substrate.

3. An electronic device as defined in claim 1, wherein at least one of said guide sections is a substrate portion in which a penetrating hole for the conductive member to flow thereinto is formed in said substrate.

4. An electronic device as defined in claim 1, wherein at least one of said guide sections is a dummy pattern which is provided on said substrate in juxtaposition to the connection end and in a manner to be spaced away from the connection end.

5. An electronic device as defined in claim 1, wherein at least one of said guide sections is a dummy wiring line which is laid in continuation to the connection end on said substrate.

6. An electronic device as defined in claim 1, wherein at least one of said guide sections is provided at a periphery of the corresponding connection end and on a side away from the other connection end.

7. An electronic device as defined in claim 1, wherein at least one of said guide sections is provided at a periphery of the corresponding connection end and on a side near to the other connection end.
